(19) United States
(12) Patent Application Publication
(10) Pub. No.: US 2025/0309205 A1
(43) Pub. Date: Oct. 2, 2025

(54) SEMICONDUCTOR PACKAGE HAVING CHIPS ARRANGED IN A STEP TYPE STRUCTURE

(71) Applicant: SAMSUNG ELECTRONICS CO., LTD., Suwon-Si (KR)

(72) Inventors: Hyeonjeong Hwang, Suwon-si (KR); Sangjin Baek, Suwon-si (KR); Kimin Cheong, Suwon-si (KR)

(21) Appl. No.: 19/029,143

(22) Filed: Jan. 17, 2025

(30) Foreign Application Priority Data
Mar. 29, 2024 (KR) 10-2024-0043676

(51) Int. Cl. H01L 25/16; H01L 21/56; H01L 23/00; H01L 23/31; H01L 23/538; H10B 80/00; H10D 80/30

(52) U.S. Cl. CPC H01L 25/16; H01L 23/5386; H01L 24/20; H01L 24/24; H01L 24/29; H01L 24/32; H01L 24/73; H10B 80/00; H10D 80/30; H01L 21/56; H01L 23/3128; H01L 24/19; H01L 2224/19; H01L 2224/214; H01L 2224/215; H01L 2224/24225; H01L 2224/29; H01L 2224/29541; H01L 2224/32145; H01L 2224/73267; H01L 2225/06517; H01L 2225/06562; H01L 2924/1431

(57) ABSTRACT

A semiconductor package includes a rewiring structure, a first chip on the rewiring structure, a first adhesive layer on an upper surface of the first chip, a first seed layer on an upper surface of the first adhesive layer, a first metal layer on a side surface of the first chip, a first conductive pillar on the rewiring structure and spaced apart from the first metal layer in a first horizontal direction, a second chip on an upper surface of the first seed layer, and offset stacked from the first chip in the first horizontal direction, and a second adhesive layer on an upper surface of the second chip, wherein the first conductive pillar overlaps the second chip in a vertical direction, and a portion of the first seed layer is disposed between the first conductive pillar and the second chip.

### CROSS-REFERENCE TO RELATED APPLICATION

This application is based on and claims ranking under 35 U.S.C. § 119 to Korean Patent Application No. 10-2024-0043676, filed on Mar. 29, 2024, in the Korean Intellectual Property Office, the disclosure of which is incorporated by reference herein in its entirety.

### BACKGROUND

### 1. Technical Field

The inventive concept relates to a semiconductor package, and more particularly, to a semiconductor package including a plurality of semiconductor chips, which are stacked in a vertical direction.

### 2. Discussion of Related Art

Semiconductor packages may be manufactured by implementing integrated circuit chips in a form appropriate for use in electronic products. In general, semiconductor packages may be manufactured by mounting semiconductor chips on printed circuit boards (PCBs) and electrically connecting the semiconductor chips to one another by using bonding wires or bumps. With recent developments in the electronics industry, semiconductor packages have been developed in various ways with the aim of miniaturization, weight reduction, and/or reduction of manufacturing costs. For example, in a multi-chip package, a plurality of semiconductor chips may be sequentially attached on a package substrate in a cascade structure.

### SUMMARY

The inventive concept provides a semiconductor package with simplified work processes and improved thermal characteristics.

In addition, aspects of the inventive concept are not limited to those mentioned above, and other aspects may be clearly understood by those of ordinary skill in the art from the following descriptions.

The inventive concept provides semiconductor packages as described below.

According to an aspect of the inventive concept, there is provided a semiconductor package including a rewiring structure, a first chip on the rewiring structure, a first adhesive layer on an upper surface of the first chip, a first seed layer on an upper surface of the first adhesive layer, a first metal layer on a side surface of the first chip, a first conductive pillar on the rewiring structure and spaced apart from the first metal layer in a first horizontal direction, a second chip on an upper surface of the first seed layer, and offset stacked from the first chip in the first horizontal direction, and a second adhesive layer on an upper surface of the second chip, wherein the first conductive pillar overlaps the second chip in a vertical direction, and a portion of the first seed layer is disposed between the first conductive pillar and the second chip.

According to another aspect of the inventive concept, there is provided a semiconductor package including a rewiring structure, a first chip on the rewiring structure, a first adhesive layer on an upper surface of the first chip, a first seed layer on an upper surface of the first adhesive layer, a first metal layer covering a side surface of the first chip, a plurality of first conductive pillars on the rewiring structure and spaced apart from the first metal layer in a first horizontal direction, a second chip on an upper surface of the first seed layer, and offset stacked from the first chip in the first horizontal direction, a second adhesive layer on an upper surface of the second chip, a second seed layer on an upper surface of the second adhesive layer, a second metal layer covering a side surface of the second chip, a plurality of second conductive pillars on at least some of the plurality of first conductive pillars and spaced apart from the second metal layer in the first horizontal direction, a third chip on an upper surface of the second seed layer, and offset stacked from the second chip in the first horizontal direction, a third adhesive layer on an upper surface of the third chip, a third seed layer on an upper surface of the third adhesive layer, a third metal layer covering a side surface of the third chip, a third conductive pillar on a second conductive pillar of the plurality of second conductive pillars and first conductive pillar of the plurality of first conductive pillars, and spaced apart from the third metal layer in the first horizontal direction, a fourth chip on an upper surface of the third seed layer, and offset stacked from the third chip in the first horizontal direction, and a fourth adhesive layer on an upper surface of the fourth chip, wherein the third conductive pillar overlaps the fourth chip in the vertical direction, wherein at least one second conductive pillar of the plurality of second conductive pillars overlaps the third chip in the vertical direction, and wherein at least one first conductive pillar of the plurality of first conductive pillars overlaps the second chip in the vertical direction.

According to another aspect of the inventive concept, there is provided a semiconductor package including a rewiring structure including a rewiring pattern and a rewiring insulating layer covering the rewiring pattern, a first chip on the rewiring structure, a first adhesive layer on an upper surface of the first chip, a first seed layer covering the upper surface of the first adhesive layer, a first metal layer extending from the first seed layer, covering side surfaces of the first chip, and in contact with the rewiring structure, a plurality of first conductive pillars on the rewiring structure and spaced apart from the first metal layer in a first horizontal direction, a second chip on an upper surface of the first seed layer, and offset stacked from the first chip in the first horizontal direction, a second adhesive layer on an upper surface of the second chip, a second seed layer covering an upper surface of the second adhesive layer, a second metal layer extending from the second seed layer to a lower surface of the second chip in a vertical direction, and covering side surfaces of the second chip, a plurality of second conductive pillars overlapping at least some of the plurality of first conductive pillars in a vertical direction, and spaced apart from the second metal layer in the first horizontal direction, a third chip on an upper surface of the second seed layer, and offset stacked from the second chip in the first horizontal direction, a third adhesive layer on an upper surface of the third chip, a third seed layer on an upper surface of the third adhesive layer, a third metal layer extending from the third seed layer, and covering at least one side surface among a plurality of side surfaces of the third chip, a third conductive pillar overlapping a second conductive pillar of the plurality of plurality of second conductive pillars in the vertical direction, and spaced apart from the third metal layer in the first horizontal direction, a fourth chip on an upper surface of the third seed layer, and offset stacked from the third chip in the first horizontal direction, a fourth adhesive layer on an upper surface of the fourth chip, and a molding member surrounding the first chip, the second chip, the third chip, and the fourth chip, wherein the third conductive pillar overlaps the fourth chip in the vertical direction, wherein at least one second conductive pillar of the plurality of second conductive pillars overlaps the third chip in the vertical direction, wherein at least one first conductive pillar of the plurality of first conductive pillars overlaps the second chip in the vertical direction, wherein a portion of the first seed layer is disposed between the at least some of the plurality of first conductive pillars and the plurality of second conductive pillars, a portion of the second seed layer is disposed between the second conductive pillar of the plurality of second conductive pillars and the third conductive pillar, and a portion of the third seed layer is disposed between the third conductive pillar and the fourth chip, and wherein at least one side surface among the side surfaces of the third chip is covered by the second seed layer.

### BRIEF DESCRIPTION OF THE DRAWINGS

Embodiments will be more clearly understood from the following detailed description taken in conjunction with the accompanying drawings in which:

FIG. 1 is a schematic cross-sectional view of a semiconductor package according to an embodiment;

FIG. 2 is a cross-sectional view taken along line X1-X1′ in FIG. 1;

FIG. 3 is a cross-sectional view taken along line X2-X2′ in FIG. 1;

FIG. 4 is a schematic cross-sectional view of a semiconductor package according to an embodiment;

FIG. 5 is a schematic cross-sectional view of a semiconductor package according to an embodiment;

FIG. 6 is a schematic cross-sectional view of a semiconductor package according to an embodiment; and

FIGS. 7-23 are cross-sectional views to describe a method of manufacturing a semiconductor package, according to embodiments.

### DETAILED DESCRIPTION

Hereinafter, embodiments of the inventive concept are described in detail with reference to the accompanying drawings. The same reference numerals are used for the same constituent elements in the drawings, and duplicate descriptions thereof may be omitted.

The disclosure allows for various changes and numerous embodiments, specific embodiments will be illustrated in the drawings and described in detail in the written description. However, this is not intended to limit embodiments to particular modes of practice, and it is to be appreciated that all changes, equivalents, and substitutes that do not depart from the spirit and technical scope of the inventive concept are encompassed by the disclosure. In the disclosure, certain detailed descriptions may be omitted when they serve to obscure the essence of the inventive concept.

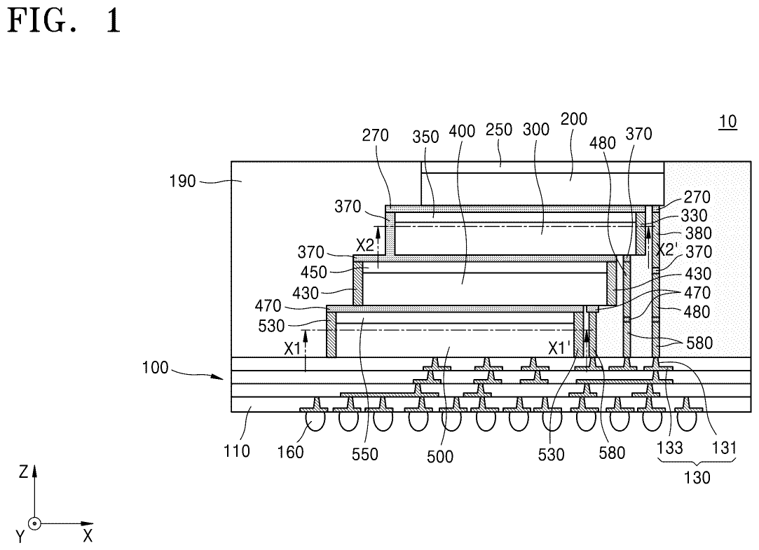

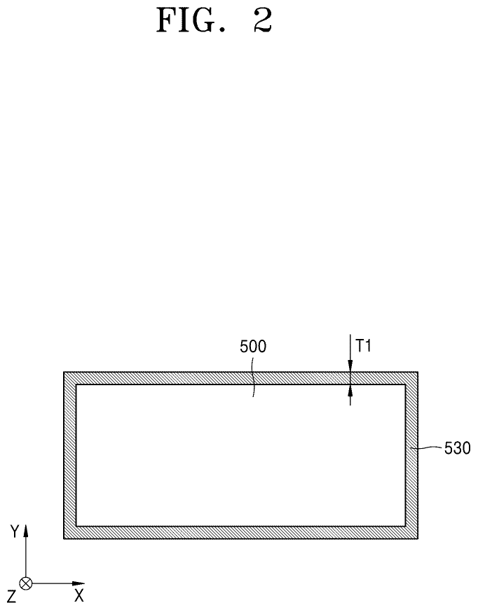

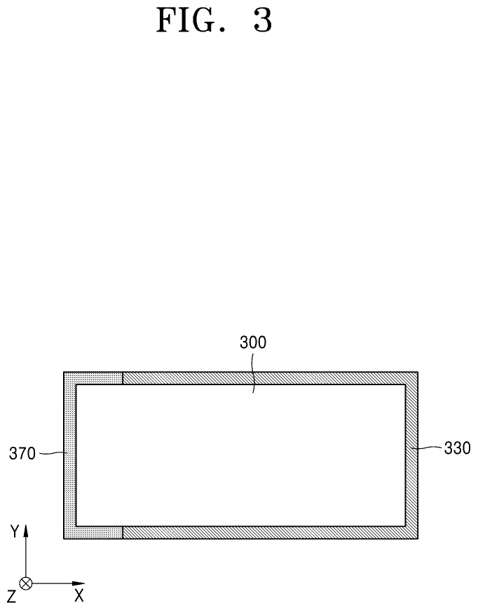

FIG. 1 is a schematic cross-sectional view of a semiconductor package 10 according to an embodiment. FIG. 2 is a cross-sectional view taken along line X1-X1′ in FIG. 1. FIG. 3 is a cross-sectional view taken along line X2-X2′ in FIG. 1.

Referring to FIG. 1, FIG. 2, and FIG. 3, the semiconductor package 10 may include a rewiring structure 100, a first chip 500, a second chip 400, a third chip 300, a fourth chip 200, and a molding member 190. The rewiring structure 100 may be disposed under the first chip 500, and may be electrically connected to each of the first chip 500, the second chip 400, the third chip 300, and the fourth chip 200. The rewiring structure 100 may include an upper surface and a lower surface, which are opposite to each other. At least one of the upper surface and the lower surface of the rewiring structure 100 may include a flat surface.

The rewiring structure 100 may include a rewiring insulating layer 110 and a rewiring pattern 130. The rewiring insulating layer 110 may be provided as a plurality of layers, which may be stacked. The rewiring pattern 130 may be formed to penetrate the rewiring insulating layer 110 from the upper surface to the lower surface of the rewiring structure 100. For example, the rewiring pattern 130 may be provided as a plurality of rewiring patterns, which may be stacked, each rewiring pattern penetrating a layer of the rewiring insulating layer 110. The rewiring pattern 130 may function as an electrical connection path penetrating from the upper surface to the lower surface of the rewiring structure 100.

In the following drawings, a direction, in which a plurality of rewiring insulating layers 110 are stacked, may be understood as a Z-axis direction, and an X-axis direction and a Y-axis direction may be understood as directions perpendicular to each other in a plane having the Z-axis direction as a normal vector. In other words, the X-axis direction and the Y-axis direction may represent directions parallel with the upper surface or the lower surface of the rewiring structure 100, and the X-axis direction and the Y-axis direction may be perpendicular to each other. The Z-axis direction may represent a direction perpendicular to the upper surface or the lower surface of the rewiring structure 100, that is, a direction perpendicular to an X-Y flat surface. In addition, in the following drawings, a first horizontal direction, a second horizontal direction, and a vertical direction may be understood as follows. The first horizontal direction may be understood as the X-axis direction, the second horizontal direction may be understood as the Y-axis direction, and the vertical direction may be understood as the Z-axis direction.

The rewiring pattern 130 may be electrically connected to a first conductive pillar 580 and the first chip 500. The rewiring pattern 130 may include a rewiring via pattern 131 and a rewiring line pattern 133. The rewiring line pattern 133 may have shape extending in the rewiring insulating layer 110 in a first horizontal direction X. According to some embodiments, the rewiring line pattern 133 may be provided to each of the plurality of rewiring insulating layers 110, which are stacked in a vertical direction Z. For example, the rewiring line pattern 133 may be disposed on a lower surface of each of the plurality of rewiring insulating layers 110. The rewiring via pattern 131 may extend in the vertical direction Z, and may penetrate at least one rewiring insulating layer 110 in the vertical direction Z. The rewiring via pattern 131 may electrically connect different line patterns of the rewiring line patterns 133 respectively formed on the rewiring insulating layers 110, which are different from each other. The rewiring via pattern 131 may electrically connect the rewiring line pattern 133 to the first conductive pillar 580 and the first chip 500.

In some embodiments, the rewiring via pattern 131 may have a tapered shape in which a horizontal width decreases in the vertical direction Z as the rewiring via pattern 131 extends from a lower side to an upper side. For example, the rewiring via pattern 131 may have a decreasing horizontal width toward the first chip 500. In some embodiments, the rewiring via pattern 131 may have a tapered shape in which a horizontal width increases as a height in the vertical direction Z increases. For example, the rewiring via pattern 131 may have a decreasing horizontal width toward an external connection bump 160.

According to some embodiments, the rewiring insulating layer 110 may include a photo imageable dielectric (PID) or photosensitive polyimide (PSPI), and the rewiring pattern 130 may include a metal or a metal alloy. The rewiring pattern 130 may include, copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), but is not limited thereto. In some embodiments, the rewiring pattern 130 may be formed by stacking a metal or a metal alloy on a seed layer. The seed layer may include Cu, Ti, titanium nitride, or titanium tungsten. According to some embodiments, the rewiring line pattern 133 may be formed together with the rewiring via pattern 131 to form an unitary body without a boundary therebetween.

In some embodiments, the rewiring structure 100 may also include a printed circuit board (PCB). In this case, the rewiring structure 100 may be understood as a wiring structure, the rewiring insulating layer 110 may be understood as a wiring insulating layer, and the rewiring pattern 130 may be understood as a wiring pattern. According to some embodiments, the rewiring insulating layer 110 may include at least one material of phenol resin, epoxy resin, or polyimide. The rewiring insulating layer 110 may include at least one material of, for example, flame retardant 4 (FR4), tetrafunctional epoxy, polyphenylene ether, epoxy/polyphenylene oxide, bismaleimide triazine (BT), thermount, cyanate ester, polyimide, or liquid crystal polymer. In addition, the rewiring pattern 130 may include Cu, Ni, stainless steel, or beryllium copper.

The external connection bump 160 may be disposed under the rewiring structure 100. For example, the external connection bump 160 may be disposed on the lower surface of the rewiring structure 100. The external connection bump 160 may be electrically connected to an external device, for example, a motherboard. The external connection bump 160 may be electrically connected to the rewiring pattern 130. The external connection bump 160 may transfer an electrical signal transferred between the first chip 500 and an external device via the rewiring pattern 130. The rewiring pattern 130 may be electrically connected to an external device via the external connection bump 160. The external connection bump 160 may include a conductive material, for example, at least one of a solder, Sn, silver (Ag), Cu, or Al.

The first chip 500 may be disposed on the rewiring structure 100. For example, the first chip 500 may be disposed on the upper surface of the rewiring structure 100. The first chip 500 may be electrically connected to the rewiring structure 100. The first chip 500 may be mounted on the rewiring structure 100 so that a surface of the first chip 500 with one or more semiconductor devices formed thereon may face the rewiring structure 100. For example, the first chip 500 may include a semiconductor substrate, and may be mounted on the rewiring structure 100 so that an active surface of the semiconductor substrate may face the rewiring structure 100.

The first chip 500 may include a memory chip or a logic chip. The memory chip may include, for example, a volatile memory chip, such as dynamic random access memory (RAM) (DRAM) or static RAM (SRAM), or a non-volatile memory chip, such as phase-change RAM (PRAM), magneto-resistive RAM (MRAM), ferroelectric RAM (FeRAM), or resistive RAM (RRAM). The logic chip may include, for example, a microprocessor, such as a central processing unit (CPU), a graphics processing unit (GPU), or an application processor (AP), an analog device, or a digital signal processor.

A first adhesive layer 550 may be disposed on the first chip 500. The first adhesive layer 550 may be arranged between a first seed layer 470 and the first chip 500. The first adhesive layer 550 may include a layer configured to attach the first seed layer 470 to the first chip 500. The first seed layer 470 and the first chip 500 may be fixed to each other by the first adhesive layer 550. The first adhesive layer 550 may include a film having an adhesion property by itself. For example, the first adhesive layer 550 may include a double-sided adhesive film. In some embodiments, the first adhesive layer 550 may include a tape-type material layer, a liquid coating cured material layer, or a combination thereof. In addition, the first adhesive layer 550 may include a thermal setting structure, thermal plastic, or ultraviolet (UV)-cure material, or a combination thereof. The first adhesive layer 550 may be referred to as a die attach film (DAF) or a non-conductive film (NCF).

A first metal layer 530 may be formed from the first seed layer 470. The first metal layer 530 may be physically connected to the first seed layer 470. The first metal layer 530 may be disposed on side surfaces the first adhesive layer 550 and the first chip 500. The first metal layer 530 may cover the side surfaces of each of the first adhesive layer 550 and the first chip 500. A thickness Tl of the first metal layer 530 in horizontal directions (X and Y directions) may be in a range of about 1 micrometers (μm) to about 50 μm.

According to some embodiments, the first metal layer 530 may cover all side surfaces of each of the first adhesive layer 550 and the first chip 500. For example, in a case that the first adhesive layer 550 and the first chip 500 have a rectangular shape in plan view, the first metal layer 530 may cover the four side surfaces of the first adhesive layer 550 in the horizontal directions (X and Y directions), and the four side surfaces of the first chip 500 in the horizontal directions (X and Y directions), as illustrated in FIG. 2. The first metal layer 530 may be formed to extend downwardly in the vertical direction Z from the first seed layer 470 to cover the side surfaces of each of the first adhesive layer 550 and the first chip 500. In this case, the first metal layer 530 may extend downwardly in the vertical direction Z from a lower surface of the first seed layer 470 to the upper surface of the rewiring structure 100. The first metal layer 530 may be in physical contact with the upper surface of the rewiring structure 100.

The first adhesive layer 550 and first chip 500 may have a shape in a plan view including a rectangular shape. The shape of the first adhesive layer 550 and the first chip 500 in plan view is not limited thereto, and the shape of the first adhesive layer 550 and the first chip 500 may be variously formed.

In some embodiments, the first metal layer 530 may cover a portion of the side surfaces of the first adhesive layer 550. For example, the first metal layer 530 may extend downwardly in the vertical direction Z from the first seed layer 470 to cover the side surfaces of the first adhesive layer 550, and the first metal layer 530 may extend to a vertical level above the upper surface of the first chip 500, and a lower portion of the side surfaces of the first adhesive layer 550 may be exposed by the first metal layer 530. In this case, the lower portion of the side surfaces of the first adhesive layer 550 may be covered by the molding member 190.

In some embodiments, the first metal layer 530 may completely cover side surfaces of the first adhesive layer 550, while exposing a portion of the side surfaces of the first chip 500. For example, while the first metal layer 530 may extend downwardly in the vertical direction Z from the first seed layer 470 to completely cover the side surfaces of the first adhesive layer 550 and an upper portion of the side surfaces of the first chip 500, the first metal layer 530 may extend to a vertical level above the upper surface of the rewiring structure 100, and the first metal layer 530 may expose the lower portion of the side surfaces of the first chip 500. In this case, the first metal layer 530 may be disposed apart from the upper surface of the rewiring structure 100 in the vertical direction Z, and the lower portion of the side surfaces of the first chip 500 may be covered by the molding member 190.

According to some embodiments, the first metal layer 530 may include the same material as the first conductive pillar 580. For example, the first metal layer 530 may include Cu. However, the first metal layer 530 is not limited thereto.

The first conductive pillar 580 may be spaced apart from the first chip 500. For example, first conductive pillar 580 may be spaced apart from the first chip 500 in the horizontal directions (X and Y directions). The first conductive pillar 580 may be spaced apart from the first metal layer 530 in the horizontal directions (X and Y directions). The first conductive pillar 580 may be formed from the first seed layer 470. According to some embodiments, the first conductive pillar 580 may be provided in plural. The plurality of first conductive pillars 580 may be spaced apart from each other. For example, the plurality of first conductive pillars 580 may be spaced apart from each other in the horizontal directions (X and Y direction). Each of the plurality of first conductive pillars 580 may extend in the vertical direction Z. Each of the plurality of first conductive pillars 580 may be electrically connected to the rewiring structure 100. Each of the plurality of first conductive pillars 580 may be electrically connected to the rewiring pattern 130 of the rewiring structure 100.

At least one of the plurality of first conductive pillars 580 may be disposed between the second chip 400 and the rewiring structure 100. The first conductive pillar 580 between the second chip 400 and the rewiring structure 100 may overlap the second chip 400 in the vertical direction Z. The first conductive pillar 580 between the second chip 400 and the rewiring structure 100 may function as an electrical path between the second chip 400 and the rewiring structure 100. In other words, the first conductive pillar 580 between the second chip 400 and the rewiring structure 100 may electrically connect the second chip 400 to the rewiring structure 100. In this case, the first seed layer 470 may be disposed between the first conductive pillar 580, which may be between the second chip 400 and the rewiring structure 100, and the second chip 400.

Some of the plurality of first conductive pillars 580 may be disposed between a second conductive pillar 480 and the rewiring structure 100. The first conductive pillars 580 between the second conductive pillar 480 and the rewiring structure 100 may not overlap the second chip 400 in the vertical direction Z. The first conductive pillars 580 between the second conductive pillar 480 and the rewiring structure 100 may function as an electrical path between the second conductive pillar 480 and the rewiring structure 100. In other words, the first conductive pillars 580 between the second conductive pillar 480 and the rewiring structure 100 may electrically connect the second conductive pillar 480 to the rewiring structure 100. In this case, the first seed layer 470 may be disposed on an upper surface of each of the first conductive pillars 580 between the second conductive pillar 480 and the rewiring structure 100.

The first seed layer 470 may function as a seed for forming the first metal layer 530 and the first conductive pillars 580. The first seed layer 470 may cover the entire upper surface of the first adhesive layer 550. In addition, the first seed layer 470 may cover an upper surface of each of the first conductive pillars 580. In this case, the first seed layer 470 covering the upper surface of the first adhesive layer 550 may be spaced apart from the first seed layer 470 covering the first conductive pillar 580 in the first horizontal direction X.

According to some embodiments, a footprint of the first seed layer 470 covering the upper surface of the first adhesive layer 550 may be greater than that of the first adhesive layer 550. The footprint of the first seed layer 470 covering the upper surface of the first adhesive layer 550 may be greater than that of the first chip 500. The first seed layer 470 may include Ti, titanium nitride (TiN), Cu, etc.

The second chip 400 may be offset stacked on the first chip 500 in the first horizontal direction X. In other words, the second chip 400 may be stacked in a cascade type structure, that is, in a step type structure above the first chip 500 in the first horizontal direction X. The second chip 400 may be disposed on an upper surface of the first seed layer 470, and offset stacked on the first seed layer 470 in the first horizontal direction X. A first portion of the upper surface of the first seed layer 470 may be covered by the second chip 400, and a second portion of the upper surface of the first seed layer 470 may be exposed from the second chip 400 upwardly in the vertical direction Z.

The second chip 400 may be arranged so that a surface with a plurality of individual devices formed thereon faces the first chip 500. The second chip 400 may be electrically connected to the rewiring structure 100 via the first seed layer 470 and the first conductive pillar 580. A second adhesive layer 450 may be disposed on an upper surface of the second chip 400. The second adhesive layer 450 may be arranged between the second chip 400 and a second seed layer 370. The second adhesive layer 450 may include a layer configured to attach the second seed layer 370 to the second chip 400. The second seed layer 370 and the second chip 400 may be fixed by using the second adhesive layer 450.

A second metal layer 430 may be formed from the second seed layer 370. The second metal layer 430 may be physically connected to the second seed layer 370. The second metal layer 430 may cover the side surfaces of each of the second adhesive layer 450 and the second chip 400. According to some embodiments, the second metal layer 430 may cover side surfaces of each of second adhesive layer 450 and the second chip 400. For example, the second metal layer 430 may cover all side surfaces of the second adhesive layer 450 in the horizontal directions (X and Y directions) and all side surfaces of the second chip 400 in the horizontal directions (X and Y directions). The second metal layer 430 may be formed to extend downwardly from the second seed layer 370 in the vertical direction Z to cover the side surfaces of each of the second adhesive layer 450 and the second chip 400. In this case, the second metal layer 430 may extend from a lower surface of the second seed layer 370 to the same vertical level as the lower surface of the second chip 400 downwardly in the vertical direction Z. In this case, a vertical level of the lower surface of the second metal layer 430 may be disposed at the same level as the vertical level of the lower surface of the second chip 400.

In some embodiments, the second metal layer 430 may cover a portion of side surfaces of the second adhesive layer 450. For example, while the second metal layer 430 may extend from the second seed layer 370 downwardly in the vertical direction Z to cover the side surfaces of the second adhesive layer 450, the second metal layer 430 may extend to a vertical level above the upper surface of the second chip 400, and the second metal layer 430 may expose the lower portion of the side surfaces of the second adhesive layer 450. In this case, the lower portion of the side surfaces of the second adhesive layer 450 may be covered by the molding member 190.

In some embodiments, the second metal layer 430 may cover all side surfaces of the second metal layer 430, while covering a portion of the side surfaces of the second chip 400. For example, while the second metal layer 430 may extend from the second seed layer 370 downwardly in the vertical direction Z to cover the side surfaces of the second adhesive layer 450 and cover the upper portion of the side surfaces of the second chip 400, the second metal layer 430 may extend to a vertical level above the lower surface of the second chip 400, and the second metal layer 430 may expose the lower portion of the side surfaces of the second chip 400. In this case, the lower portion of the side surfaces of the second chip 400 may be covered by the molding member 190.

According to some embodiments, the second metal layer 430 may include the same material as the second conductive pillar 480. For example, the second metal layer 430 may include Cu. However, the material constituting the second metal layer 430 is not limited thereto.

The second conductive pillar 480 may be spaced apart from the second chip 400. For example, the second conductive pillar 480 may be spaced apart from the second chip 400 in the horizontal directions (X and Y directions). The second conductive pillar 480 may be spaced apart from the second metal layer 430 in the horizontal directions (X and Y directions). The second conductive pillar 480 may be formed from the second seed layer 370. According to some embodiments, the second conductive pillar 480 may be provided in plural. The plurality of second conductive pillars 480 may be spaced apart from each other. For example, the plurality of second conductive pillars 480 may be spaced apart from each other in the horizontal directions (X and Y directions). Each of the plurality of second conductive pillars 480 may extend in the vertical direction Z. The second seed layer 370 may be disposed on an upper surface of each of the plurality of second conductive pillars 480. Each of the plurality of second conductive pillars 480 may be electrically connected to the first conductive pillar 580. The first seed layer 470 may be disposed on the lower surface of each of the plurality of second conductive pillars 480.

According to some embodiments, at least one of the plurality of second conductive pillars 480 may be disposed between the third chip 300 and the first conductive pillar 580. The second conductive pillar 480 between the third chip 300 and the first conductive pillar 580 may overlap the third chip 300 in the vertical direction Z. The second conductive pillar 480 between the third chip 300 and the first conductive pillar 580 may function as an electrical path between the third chip 300 and the first conductive pillar 580. In other words, the second conductive pillar 480 between the third chip 300 and the first conductive pillar 580 may electrically connect the third chip 300 to the first conductive pillar 580. In this case, the second seed layer 370 may be disposed between the second conductive pillar 480 between the third chip 300 and the first conductive pillar 580, and the third chip 300.

According to some embodiments, a vertical level of an upper surface of the second conductive pillar 480 between the third chip 300 and the first conductive pillar 580 may be disposed substantially the same as a vertical level of an upper surface of the second metal layer 430. A vertical level of a lower surface of the second conductive pillar 480 between the third chip 300 and the first conductive pillar 580 may be disposed at a lower vertical level than a vertical level of a lower surface of the second metal layer 430.

At least one of the plurality of second conductive pillars 480 may be disposed between a third conductive pillar 380 and the first conductive pillar 580. The second conductive pillar 480 between the third conductive pillar 380 and the first conductive pillar 580 may not overlap the third chip 300 in the vertical direction Z. The second conductive pillar 480 between the third conductive pillar 380 and the first conductive pillar 580 may function as an electrical path between the third conductive pillar 380 and the first conductive pillar 580. In other words, the second conductive pillar 480 between the third conductive pillar 380 and the first conductive pillar 580 may electrically connect the third conductive pillar 380 to the first conductive pillar 580. In this case, the second seed layer 370 may be disposed on the upper surface of the second conductive pillar 480 between the third conductive pillar 380 and the first conductive pillar 580.

According to some embodiments, a vertical level of the upper surface of the second conductive pillar 480 between the third conductive pillar 380 and the first conductive pillar 580 may be disposed at a lower vertical level than the vertical level of the second metal layer 430. The vertical level of the lower surface of the second conductive pillar 480 between the third conductive pillar 380 and the first conductive pillar 580 may be disposed at a lower vertical level than the vertical level of the lower surface of the second metal layer 430.

The second seed layer 370 may function as a seed for forming the second metal layer 430 and the second conductive pillars 480. The second seed layer 370 may cover all the upper surface of the second adhesive layer 450. In addition, the second seed layer 370 may cover an upper surface of each of the second conductive pillars 480. In this case, the second seed layer 370 covering the upper surface of the second adhesive layer 450 may be spaced apart from the second seed layer 370 covering the second conductive pillar 480 in the first horizontal direction X.

According to some embodiments, a planar area of the second seed layer 370 covering the upper surface of the second adhesive layer 450 may be greater than a planar area of the second adhesive layer 450. The planar area of the second seed layer 370 covering the upper surface of the second adhesive layer 450 may be greater than the planar area of the second chip 400.

The third chip 300 may be offset stacked above the second chip 400 in the first horizontal direction X. In other words, the third chip 300 may be stacked in a cascade type structure, that is, in a step type structure above the second chip 400 in the first horizontal direction X. The third chip 300 may be disposed on the upper surface of the second seed layer 370, and may be offset stacked on the upper surface of the second seed layer 370 in the first horizontal direction X. A first portion of the upper surface of the second seed layer 370 may be covered by the third chip 300, and a second portion of the upper surface of the second seed layer 370 may be exposed from the third chip 300 upwardly in the vertical direction Z.

The third chip 300 may be arranged so that a surface of the third chip 300 with a plurality of individual devices formed thereon faces the second chip 400. The third chip 300 may be connected to the rewiring structure 100 via the second seed layer 370, the second conductive pillar 480, the first seed layer 470, and the first conductive pillar 580. A third adhesive layer 350 may on the upper surface of the third chip 300. The third adhesive layer 350 may be arranged between the third chip 300 and a third seed layer 270. The third adhesive layer 350 may include a layer configured to attach the third seed layer 270 to the third chip 300. The third seed layer 270 and the third chip 300 may be fixed by using the third adhesive layer 350.

A third metal layer 330 may be formed from the third seed layer 270. The third metal layer 330 may be physically connected to the third seed layer 270. The third metal layer 330 may cover side surfaces of each of the third adhesive layer 350 and the third chip 300. According to some embodiments, the third metal layer 330 may cover three of the four side surfaces of each of the third adhesive layer 350 and the third chip 300 in the horizontal directions (X and Y directions), and may expose a remaining one side surface thereof. For example, the third metal layer 330 may cover a portion overlapping the second seed layer 370 in the vertical direction Z among the four side surfaces of the third adhesive layer 350 and the third chip 300, and may expose a portion not overlapping the second seed layer 370 in the vertical direction Z among the four side surfaces the third adhesive layer 350 and the third chip 300. According to some embodiments, as illustrated in FIG. 3, the third metal layer 330 may cover an entire portion of one side surface of the third chip 300, and two side surfaces perpendicular to the one side surface may expose a portion of the third chip 300. An area exposed by the third metal layer 330 among the side surfaces of the third chip 300 may be covered by the third seed layer 270.

According to some embodiments, the third metal layer 330 may be formed to extend from the third seed layer 270 downwardly in the vertical direction Z to cover at least one side surface of each of the third adhesive layer 350 and the third chip 300. In this case, the third metal layer 330 may extend from a lower surface of the third seed layer 270 to the same vertical level as the lower surface of the third chip 300 downwardly in the vertical direction Z. In this case, a vertical level of the lower surface of the third metal layer 330 may be disposed at the same level as the vertical level of the lower surface of the third chip 300.

In some embodiments, the third metal layer 330 may cover a portion of the side surfaces of the third adhesive layer 350. For example, the third metal layer 330 may extend downwardly in the vertical direction Z from the third seed layer 270 to cover the side surfaces of the third adhesive layer 350, and may extend to a vertical level above the upper surface of the third chip 300, and thus, may expose the lower portion of the side surfaces of the third adhesive layer 350. In this case, the lower portion of the side surfaces of the third adhesive layer 350 may be covered by the molding member 190.

In some embodiments, the third metal layer 330 may cover all side surfaces of the third adhesive layer 350, while covering a portion of the side surfaces of the third chip 300. For example, while the third metal layer 330 may extend from the third seed layer 270 downwardly in the vertical direction Z to cover the side surfaces of the third adhesive layer 350 and cover the upper portion of the side surfaces of the third chip 300, the third metal layer 330 may extend to a vertical level above the lower surface of the third chip 300, and the third metal layer 330 may expose the lower portion of the side surfaces of the third chip 300. In this case, the lower portion of the side surfaces of the third chip 300 may be covered by the molding member 190.

According to some embodiments, the third metal layer 330 may include the same material as the third conductive pillar 380. For example, the third metal layer 330 may include Cu. However, the material constituting the third metal layer 330 is not limited thereto.

The third conductive pillar 380 may be spaced apart from the third chip 300. For example, the third conductive pillar 380 may be spaced apart from the third chip 300 in the horizontal directions (X and Y directions). The third conductive pillar 380 may be spaced apart from the third metal layer 330 in the horizontal directions (X and Y directions). The third conductive pillar 380 may be formed from the third seed layer 270. In some embodiments, at least one third conductive pillars 380 may be provided. When two or more third conductive pillars 380 are provided, the third conductive pillars 380 may be spaced apart from each other. For example, the third conductive pillars 380 may be spaced apart from each other in the horizontal directions (X and Y directions). The third conductive pillar 380 may extend in the vertical direction Z. The third seed layer 270 may be disposed on an upper surface of the third conductive pillar 380. The third conductive pillar 380 may be electrically connected to the second conductive pillar 480. The second seed layer 370 may be disposed on a lower surface of the third conductive pillar 380. At least one third conductive pillar 380 may overlap the fourth chip 200 in the vertical direction Z.

According to embodiments, the third conductive pillar 380 may be disposed between the fourth chip 200 and the second conductive pillar 480. The third conductive pillar 380 may function as an electrical path between the fourth chip 200 and the second conductive pillar 480. In other words, the third conductive pillar 380 may electrically connect the fourth chip 200 to the second conductive pillar 480. In this case, the third seed layer 270 may be disposed between the third conductive pillar 380 and the fourth chip 200.

According to some embodiments, the upper surface of the third conductive pillar 380 may be disposed substantially at the same vertical level as an upper surface of the third metal layer 330. The lower surface of the third conductive pillar 380 may be disposed at a lower vertical level than the lower surface of the third metal layer 330.

The third seed layer 270 may function as a seed for forming the third metal layer 330 and the third conductive pillar 380. The third seed layer 270 may cover the entire upper surface of the third adhesive layer 350. The third seed layer 270 may cover the side surfaces of the third chip 300. In this case, the third seed layer 270 may cover a portion of the side surface of the third chip 300, which is exposed by the third metal layer 330. The third seed layer 270 may cover the upper surface of the third conductive pillar 380. In this case, the third seed layer 270 covering the upper surface of the third adhesive layer 350 and the third seed layer 270 covering the third conductive pillar 380 may be spaced apart from each other in the first horizontal direction X.

According to some embodiments, a planar area of the third seed layer 270 covering the upper surface of the third adhesive layer 350 may be greater than a planar area of the third adhesive layer 350. The planar area of the third seed layer 270 covering the upper surface of the third adhesive layer 350 may be greater than a planar area of the third chip 300.

The fourth chip 200 may be offset stacked above the third chip 300 in the first horizontal direction X. In other words, the fourth chip 200 may be stacked above the third chip 300 in a cascade type structure, that is, in a step type structure, in the first horizontal direction X. The fourth chip 200 may be disposed on the upper surface of the third seed layer 270, and may be offset-stacked on the upper surface of the third seed layer 270 in the first horizontal direction X. A portion of the upper surface of the third seed layer 270 may be covered by the fourth chip 200, and the remaining portion of the upper surface of the third seed layer 270 may be exposed from the fourth chip 200 upwardly in the vertical direction Z.

The fourth chip 200 may be arranged so that a surface of the fourth chip 200 with a plurality of individual devices formed thereon faces the second chip 400. The fourth chip 200 may be electrically connected to the rewiring structure 100 via the third seed layer 270, the third conductive pillar 380, the second seed layer 370, the second conductive pillar 480, the first seed layer 470, and the first conductive pillar 580. A fourth adhesive layer 250 may be disposed on an upper surface of the fourth chip 200.

The molding member 190 may surround the first chip 500, the second chip 400, the third chip 300, and the fourth chip 200 on the upper surface of the rewiring structure 100. An upper surface of the molding member 190 may be disposed substantially at the same vertical level as an upper surface of the fourth adhesive layer 250. The molding member 190 may be formed from a thermosetting resin such as an epoxy resin, a thermoplastic resin such as polyimide, or a resin including a reinforcing material such as an inorganic filler to these resins, specifically, from AJINOMOTO BUILD-UP FILM® (ABF), flame retardant-4 (FR-4), or bismaleimide triazine (BT), but is not limited thereto, and the molding member 190 may be formed from a molding material such as epoxy mold compound (EMC) or a photosensitive material such as photoimageable encapsulant (PIE). In some embodiments, a portion of the molding member 190 may include an insulating material, such as a silicon oxide layer, a silicon nitride layer, or a silicon oxynitride layer.

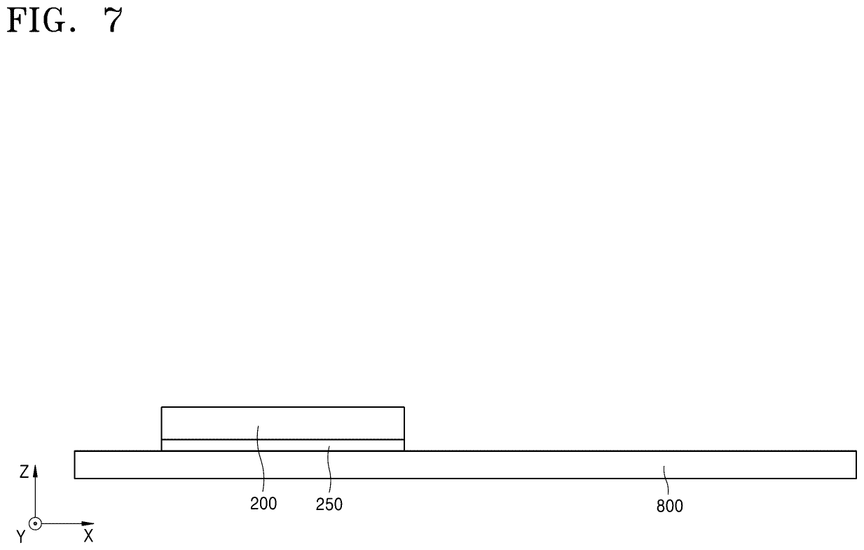

The semiconductor package 10 according to the technical idea of the inventive concept may include a plurality of chips (200, 300, 400, and 500) stacked in a step type structure, and the plurality conductive pillars (380, 480, and 580) may electrically connect between the plurality of chips (200, 300, 400, and 500) and the rewiring structure 100. The semiconductor package 10 according to the technical aspect of the inventive concept may be simplified, as described with reference to FIGS. 7-23.

In addition, the semiconductor package 10 according to the technical idea of the inventive concept includes metal layers (330, 430, and 530) formed on the side surfaces of the plurality of chips (300, 400, and 500), respectively, and the thermal characteristics of the semiconductor package 10 may also be improved.

The technical idea of the inventive concept may be adapted to a different number of chips. For example, the step type structure may include two chips, three chips as illustrated, or four or more chips. Aspects of the inventive concept are not limited to a particular number of chips.

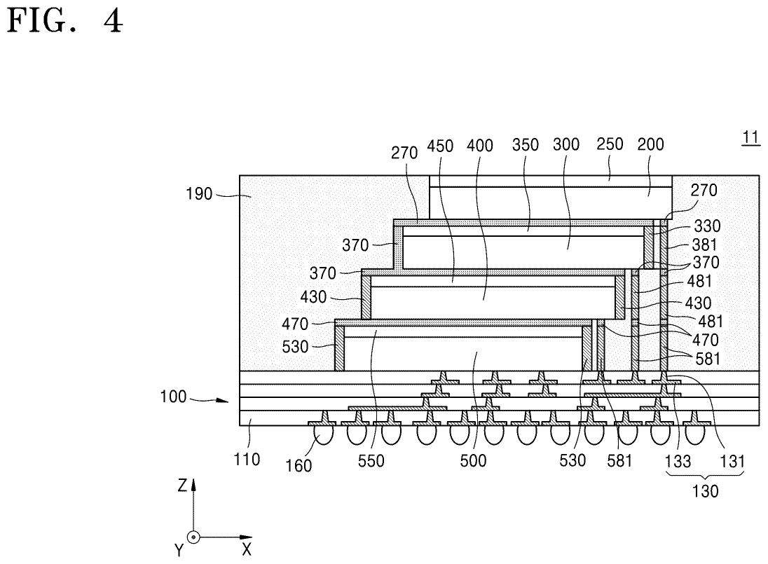

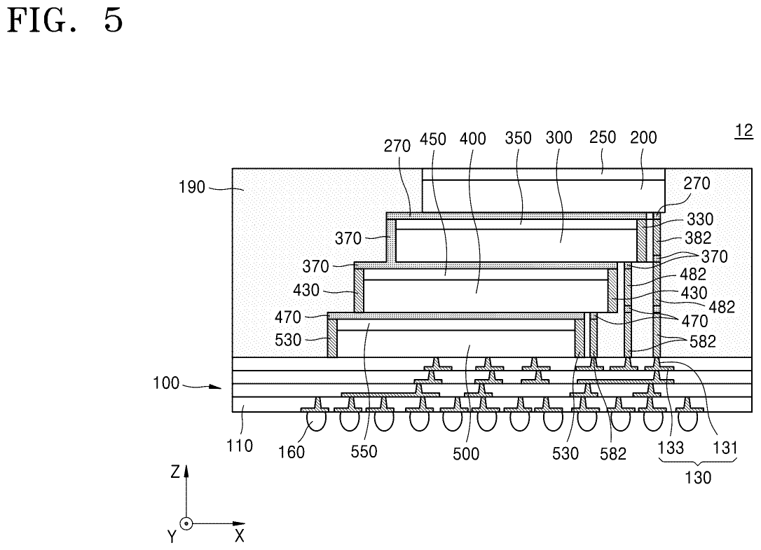

FIG. 4 is a schematic cross-sectional view of a semiconductor package 11 according to an embodiment. FIG. 5 is a schematic cross-sectional view of a semiconductor package 12 according to an embodiment. The semiconductor packages 11 and 12 of FIG. 4 and FIG. 5 may include the same or substantially similar components or features described with reference to the semiconductor package 10 of FIG. 1, FIG. 2, and FIG. 3. Duplicate descriptions thereof may be omitted or simplified in the description of the semiconductor packages 11 and 12 of FIG. 4 and FIG. 5.

Referring to FIG. 4 and FIG. 5, the semiconductor packages 11 and 12 may include the rewiring structure 100, the first chip 500, the second chip 400, the third chip 300, the fourth chip 200, and the molding member 190. The rewiring structure 100 may be disposed on a lower surface of the first chip 500. For example, the rewiring structure 100 may be disposed under the first chip 500, and may be electrically connected to each of the first chip 500, the second chip 400, the third chip 300, and the fourth chip 200. The rewiring structure 100 may include a rewiring insulating layer 110, and a rewiring pattern 130. The external connection bump 160 may be disposed on the lower surface of the rewiring structure 100. For example, the external connection bump 160 may be disposed under the rewiring structure 100. The first chip 500 may be mounted on the rewiring structure 100. The first adhesive layer 550 may be disposed on the first chip 500. The first adhesive layer 550 may be arranged between the first seed layer 470 and the first chip 500. The first metal layer 530 may be formed from the first seed layer 470. The first metal layer 530 may be physically connected to the first seed layer 470. The first metal layer 530 may cover at least a portion of the side surfaces of each of the first adhesive layer 550 and the first chip 500. The second chip 400 may be disposed on an upper surface of the first chip 500. For example, the second chip 400 may be offset stacked on the first chip 500 in the first horizontal direction X. The second adhesive layer 450 may be disposed on the upper surface of the second chip 400. The second metal layer 430 may be formed from the second seed layer 370. The second metal layer 430 may cover at least a portion of the side surfaces of each of the second adhesive layer 450 and the second chip 400. The third chip 300 may be disposed on an upper surface of the second chip 400. For example, the third chip 300 may be offset stacked above the second chip 400 in the first horizontal direction X. The third adhesive layer 350 may on the upper surface of the third chip 300. The third metal layer 330 may be formed from the third seed layer 270. The third metal layer 330 may cover at least a portion of the side surfaces of each of the third adhesive layer 350 and the third chip 300. The fourth chip 200 may be disposed on an upper surface of the third chip 300. For example, the fourth chip 200 may be offset stacked above the third chip 300 in the first horizontal direction X. The fourth adhesive layer 250 may be disposed on the upper surface of the fourth chip 200. The molding member 190 may surround the first chip 500, the second chip 400, the third chip 300, and the fourth chip 200 on the upper surface of the rewiring structure 100. The molding member 190 may expose at least a portion of an upper surface of the fourth chip 200.

The semiconductor package 11 may include a first conductive pillar 581, a second conductive pillar 481, and a third conductive pillar 381, as illustrated in FIG. 4. According to some embodiments, an upper surface of the first conductive pillar 581 may be disposed substantially at the same vertical level as an upper surface of the first metal layer 530, and a lower surface of the first conductive pillar 581 may be disposed substantially at the same vertical level as a lower surface of the first metal layer 530. An upper surface of the second conductive pillar 481 may be disposed substantially at the same vertical level as an upper surface of the second metal layer 430, and a lower surface of the second conductive pillar 481 may be disposed substantially at the same vertical level as a lower surface of the second metal layer 430. An upper surface of the third conductive pillar 381 may be disposed substantially at the same vertical level as the upper surface of the third metal layer 330, and a lower surface of the third conductive pillar 381 may be disposed substantially at the same vertical level as the lower surface of the third metal layer 330.

In addition, the semiconductor package 12 may include a first conductive pillar 582, a second conductive pillar 482, and a third conductive pillar 382, as illustrated in FIG. 5. An upper surface of the first conductive pillar 582 may be disposed substantially at the same vertical level as the upper surface of the first metal layer 530, and a lower surface of the first conductive pillar 582 may be disposed substantially at the same vertical level as the lower surface of the first metal layer 530. At least one upper surface of the second conductive pillars 482 may be disposed at a higher vertical level than the upper surface of the second metal layer 430, and a lower surface of the second conductive pillar 482 may be disposed at a higher vertical level than the lower surface of the second metal layer 430. An upper surface of the third conductive pillar 382 may be disposed substantially at the same vertical level as the upper surface of the third metal layer 330, and a lower surface of the third conductive pillar 382 may be disposed substantially at the same vertical level as the lower surface of the third metal layer 330.

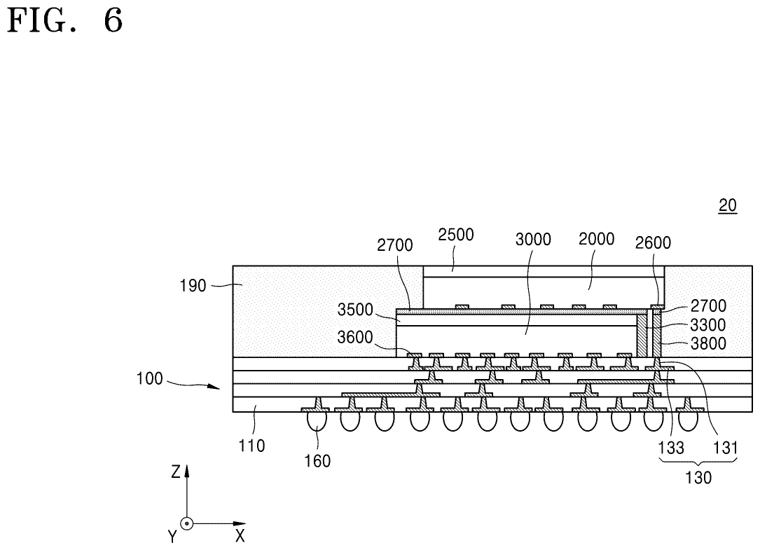

FIG. 6 is a schematic cross-sectional view of a semiconductor package 20 according to an embodiment. Hereinafter, the semiconductor package 20 of FIG. 6 may include the same or substantially similar components or features described with reference to the semiconductor package 10 of FIG. 1, FIG. 2, and FIG. 3. Duplicate descriptions thereof may be omitted or simplified in the description of the semiconductor package 20 of FIG. 6.

Referring to FIG. 6, the semiconductor package 20 may include the rewiring structure 100, a first chip 3000, a second chip 2000, and the molding member 190. The rewiring structure 100 may be disposed on a lower surface of the first chip 3000. For example, the rewiring structure 100 may be under the first chip 3000 and may be electrically connected to each of the first chip 3000 and the second chip 2000. The rewiring structure 100 may include the rewiring insulating layer 110 and the rewiring pattern 130. The external connection bump 160 may be disposed on a lower surface of the rewiring structure 100. For example, the external connection bump 160 may be under the rewiring structure 100. The first chip 3000 may be mounted on an upper surface of the rewiring structure 100. A first adhesive layer 3500 may be disposed on an upper surface of the first chip 3000. The first adhesive layer 3500 may be arranged between a first seed layer 2700 and the first chip 3000. A first metal layer 3300 may be formed from the first seed layer 2700. The first metal layer 3300 may be physically connected to the first seed layer 2700. The first metal layer 3300 may cover at least a portion of side surfaces of each of the first adhesive layer 3500 and the first chip 3000. According to some embodiments, the first metal layer 3300 may cover at least one side surface of the first metal layer 3300, and a portion exposed by the first metal layer 3300 among the side surfaces of the first metal layer 3300 may be covered by the first seed layer 2700. The second chip 2000 may be offset stacked above the first chip 3000 in the first horizontal direction X. A second adhesive layer 2500 may be disposed on an upper surface of the second chip 2000.

A first conductive pillar 3800 may be spaced apart from the first metal layer 3300. For example, the first conductive pillar 3800 may be spaced apart from the first metal layer 3300 in the horizontal directions (X and Y directions). The first seed layer 2700 may be disposed on the upper surface of the first conductive pillar 3800. The first conductive pillar 3800 may overlap the second chip 2000 in the vertical direction Z.

According to some embodiments, the first chip 3000 may include a logic chip, and the second chip 2000 may include a memory chip. A plurality of first chip pads 3600 may be provided on a lower surface of the first chip 3000. Second chip pads 2600 may be provided on a lower surface of the second chip 2000. The number of the plurality of first chip pads 3600 of the first chip 3000 may be greater than the number of the plurality of second chip pads 2600 of the second chip 2000. According to some embodiments, an upper surface of the second adhesive layer 2500 may be disposed substantially at the same vertical level as the upper surface of the molding member 190.

A bottom surface of the first chip 3000, on which the plurality of first chip pads 3600 are disposed, may be an active surface, and a top surface opposite to the bottom surface of the first chip 3000 may be an inactive surface. The plurality of first chip pads 3600 may be electrically connected to other components in the semiconductor package 20, for example, an integrated circuit. Specifically, the rewiring structure 100 may be formed on the bottom surface of the semiconductor package 20, and the plurality of first chip pads 3600 may be electrically connected to the rewiring structure 100.

A bottom surface of the second chip 2000, on which the plurality of second chip pads 2600 are disposed, may be an active surface, and a top surface opposite to the bottom surface of the second chip 2000 may be an inactive surface. The plurality of second chip pads 2600 may be electrically connected to other components in the semiconductor package 20, for example, an integrated circuit. Specifically, the plurality of second chip pads 2600 may be electrically connected to the rewiring structure 100.

FIGS. 7-23 are cross-sectional views to describe a method of manufacturing a semiconductor package, according to embodiments. Hereinafter, duplicate descriptions of the semiconductor package 10 given with reference to FIG. 1, FIG. 2, and FIG. 3 may be omitted or simplified.

Referring to FIG. 7, the fourth chip 200 may be mounted on a carrier substrate 800 by using the fourth adhesive layer 250. In this case, the fourth chip 200 may be disposed substantially the same as the fourth chip 200 in FIG. 1. According to some embodiments, an upper surface of the carrier substrate 800 may be planar and have a flat shape.

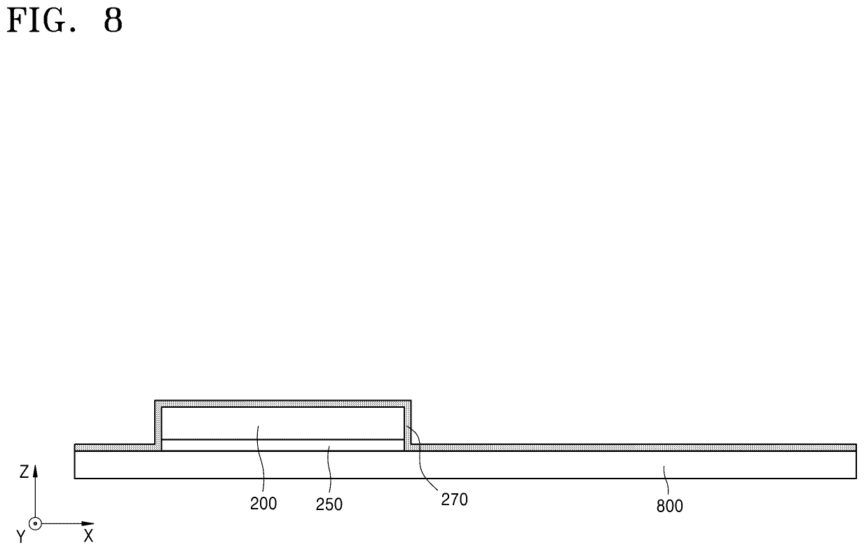

Referring to FIG. 8, the third seed layer 270 covering surfaces of the carrier substrate 800, the fourth chip 200, and the fourth adhesive layer 250 may be formed. According to some embodiments, the third seed layer 270 may tightly cover the upper surface of the carrier substrate 800, side surfaces of the fourth adhesive layer 250, and side surfaces and an upper surface of the fourth chip 200.

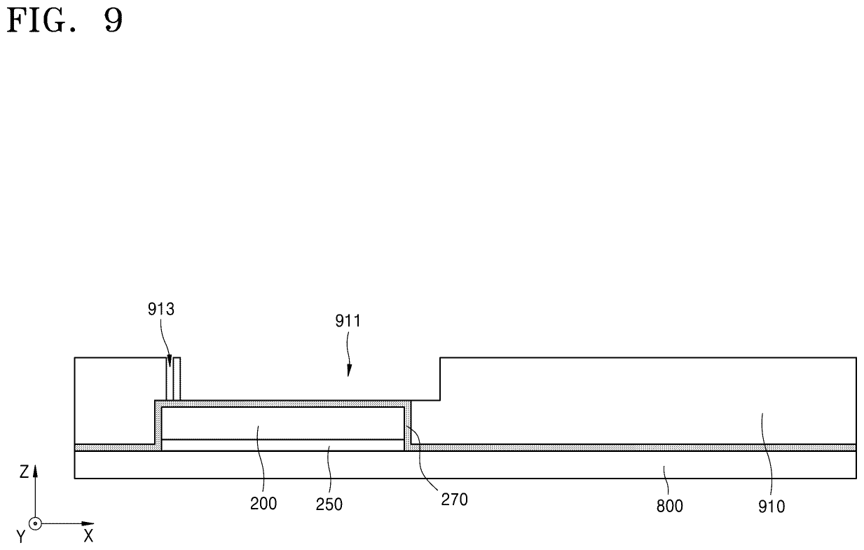

Referring to FIG. 9, a first photoresist 910 may be formed to cover the third seed layer 270. A first opening 911 and a second opening 913 may be formed in the first photoresist 910. The first opening 911 and the second opening 913 may be formed to be spaced apart from each other. For example, the first opening 911 and the second opening 913 may be formed to be spaced apart from each other in the horizontal directions (X and Y directions). The second opening 913 may be formed to overlap the fourth chip 200 in the vertical direction Z. According to some embodiments, a planar area of the first opening 911 in the horizontal directions (X and Y directions) may be greater than a planar area of the second opening 913. According to some embodiments, the planar area of the first opening 911 may be greater than a planar area of the fourth chip 200.

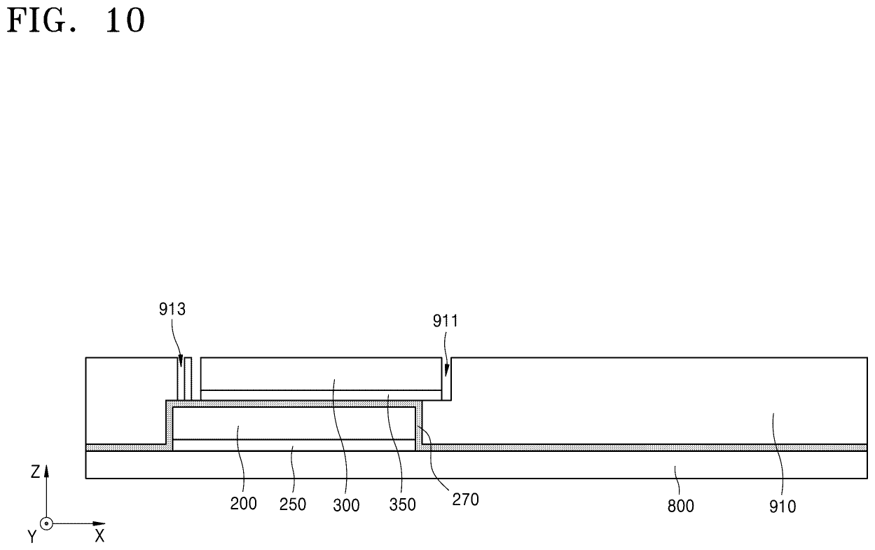

Referring to FIG. 10, the third chip 300 may be arranged in the first opening 911 of the first photoresist 910. In this case, the third chip 300 may be mounted in the first opening 911 by using the third adhesive layer 350. The third adhesive layer 350 may be arranged on the upper surface of the third seed layer 270. According to some embodiments, the planar area of the first opening 911 may be greater than a planar area of the third chip 300. At least one side surface of the third chip 300 may be spaced apart from the first photoresist 910 in the horizontal directions (X and Y directions). Accordingly, a remaining portion of the first opening 911 may be provided between the third chip 300 and the first photoresist 910.

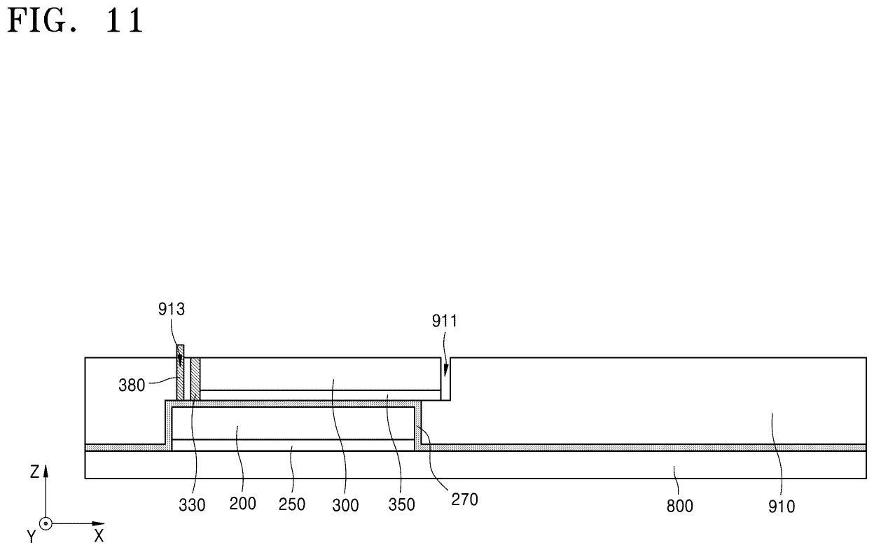

Referring to FIG. 11, the third conductive pillar 380 and the third metal layer 330 may be formed from the third seed layer 270. The third conductive pillar 380 may be formed in the second opening 913 of the first photoresist 910, and the third metal layer 330 may be formed in the first opening 911. In this case, the third metal layer 330 may be formed from the third seed layer 270, and the third metal layer 330 may be formed in a portion where the third metal layer 330 overlaps the third seed layer 270 in the vertical direction Z. Accordingly, among portions not filled by the third chip 300 in the first opening 911, the third metal layer 330 may be formed in a portion overlapping the third seed layer 270 in the vertical direction Z, and among portions not filled by the third chip 300 in the first opening 911, the third metal layer 330 may not be formed in a portion that does not overlap the third seed layer 270 in the vertical direction Z. Accordingly, among the portions not filled by the third chip 300 in the first opening 911, the portion not overlapped by the third seed layer 270 in the vertical direction Z may remain as an empty space.

According to some embodiments, a vertical level of an upper surface of the third conductive pillar 380 formed in the second opening 913 of the first photoresist 910 may be variously formed. For example, as illustrated in FIG. 11, the vertical level of the upper surface of the third conductive pillar 380 may be disposed at a level higher than the vertical level of the third metal layer 330. In some embodiments, the vertical level of the upper surface of the third conductive pillar 380 may be disposed substantially at the same vertical level as the third metal layer 330, and the vertical level of the upper surface of the third conductive pillar 380 may be disposed at a level lower than the vertical level of the third metal layer 330.

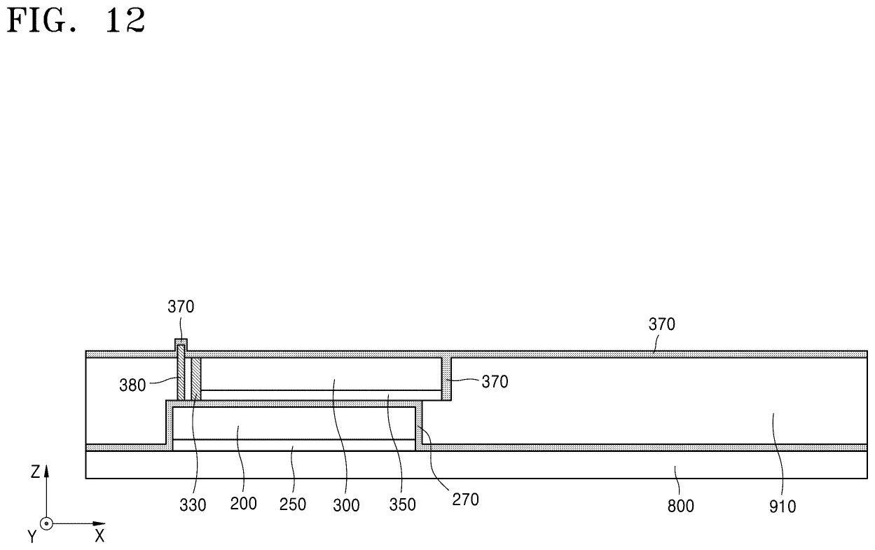

Referring to FIG. 12, the second seed layer 370 may be formed to cover the first photoresist 910, the third conductive pillar 380, the third metal layer 330, and the third chip 300. The second seed layer 370 may be a conformal layer. For example, the second seed layer 370 may cover the upper surface of the first photoresist 910, and may fill an empty space not filled by the third chip 300 and the third metal layer 330, in the first opening 911 of the first photoresist 910. Accordingly, a portion of the side surfaces of the third chip 300 may be covered by the second seed layer 370.

The second seed layer 370 may cover the upper surface of the third chip 300 and the upper surface of the third metal layer 330. In addition, the second seed layer 370 may cover the portion of the third conductive pillar 380 exposed from the first photoresist 910.

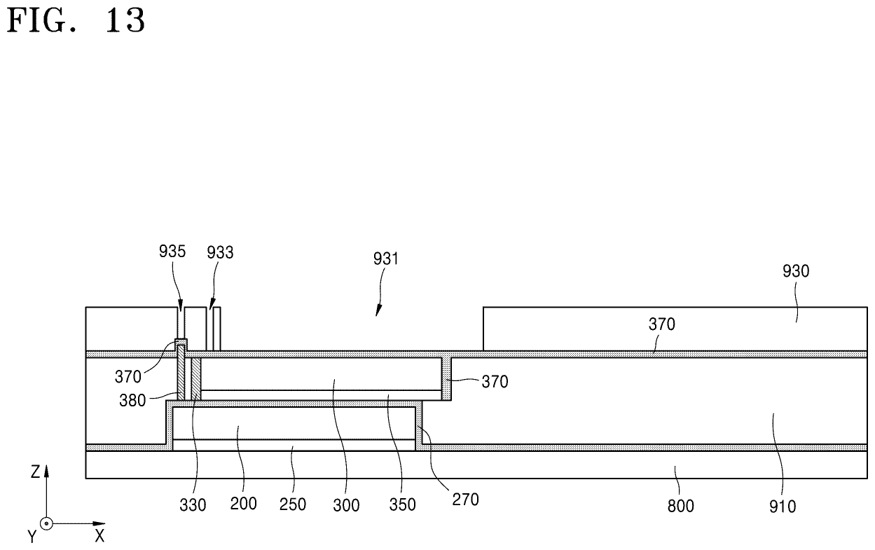

Referring to FIG. 13, a second photoresist 930 may be formed on the second seed layer 370. The second photoresist 930 may include a first opening 931, a second opening 933, and a third opening 935. The first opening 931, the second opening 933, and the third opening 935 may be formed to be spaced apart from each other. For example, first opening 931, the second opening 933, and the third opening 935 may be formed to be spaced apart from each other in the horizontal directions (X and Y directions). A planar area of the first opening 931 may be greater than a planar area of each of the second opening 933 and the third opening 935. The planar area of the first opening 931 may be greater than that of the third chip 300. The second opening 933 may be formed to overlap the third chip 300 in the vertical direction Z. The third opening 935 may be formed to overlap the third conductive pillar 380 in the vertical direction Z.

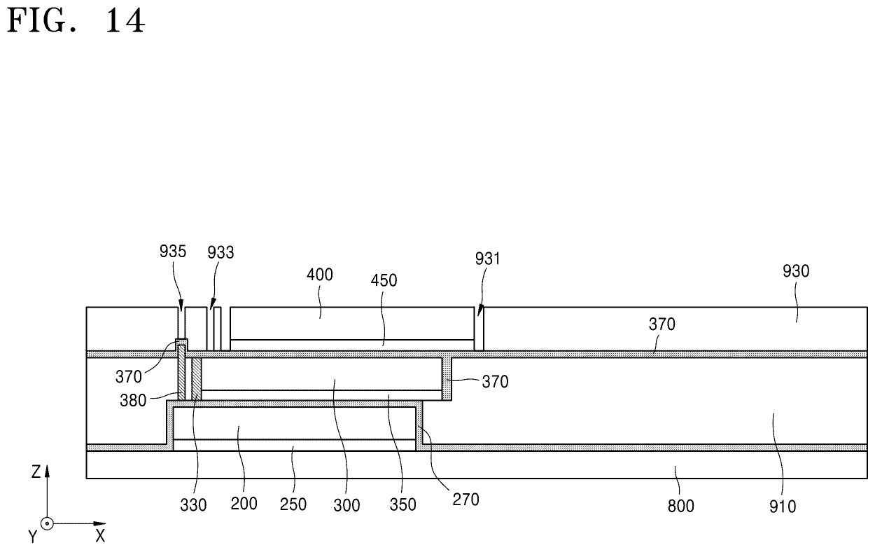

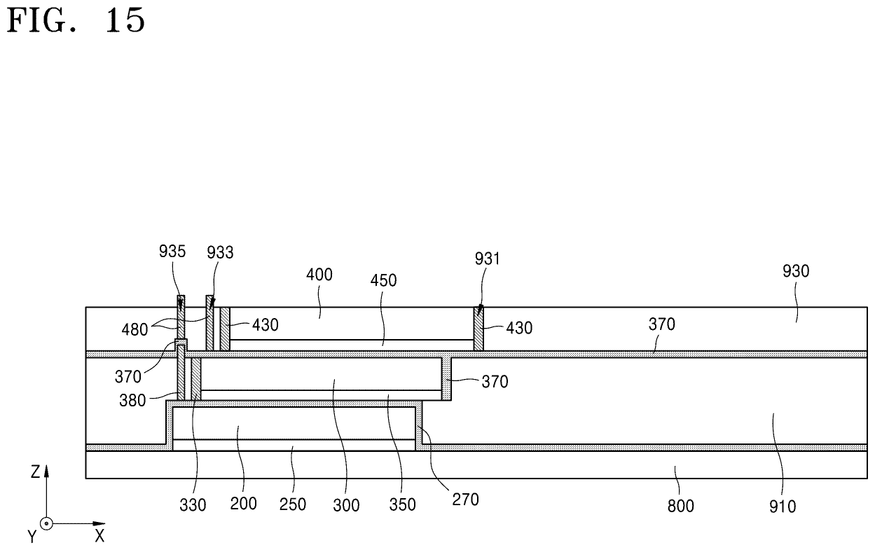

Referring to FIG. 14 and FIG. 15, the second chip 400 may be mounted on the first opening 931, the second metal layer 430 may be formed in a space between the first opening 931 and the second chip 400 by using the second seed layer 370, and the second conductive pillar 480 may be formed in each of the second opening 933 and the third opening 935. The second chip 400 may be mounted on the first opening 931 by using the second adhesive layer 450. At least one side surface of the second chip 400 may be spaced apart from the second photoresist 930 in the horizontal directions (X and Y directions). Accordingly, a remaining portion of the first opening 931 may be provided between the second chip 400 and the second photoresist 930. The side surface of the second chip 400 may be surrounded by the second metal layer 430.

According to some embodiments, vertical levels of the upper surfaces of the second conductive pillars 480 formed in each of the second opening 933 and the third opening 935 may be variously formed.

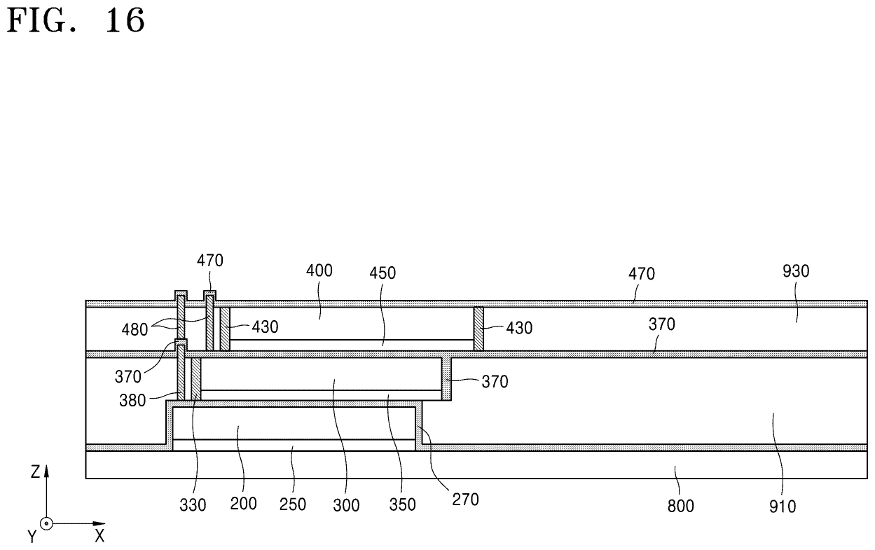

Referring to FIG. 16, the first seed layer 470 may be formed to cover the second photoresist 930, the second conductive pillars 480, and the second chip 400. The first seed layer 470 may be a conformal layer. For example, the first seed layer 470 may cover an upper surface of the second photoresist 930, and may cover a portion of the second conductive pillars 480 exposed from the second photoresist 930.

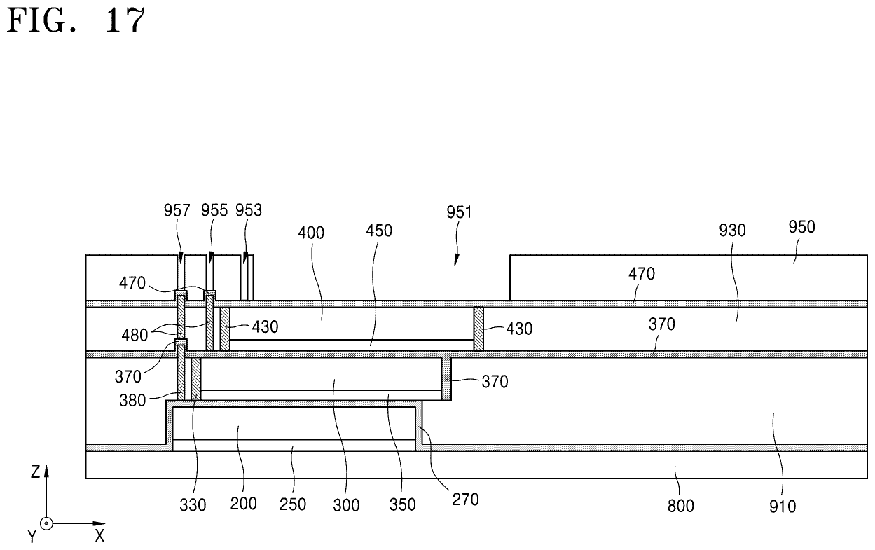

Referring to FIG. 17, a third photoresist 950 may be formed on the first seed layer 470. The third photoresist 950 may include a first opening 951, a second opening 953, a third opening 955, and a fourth opening 957. The first opening 951, the second opening 953, the third opening 955, and the fourth opening 957 may be formed to be spaced apart from each other. For example, the first opening 951, the second opening 953, the third opening 955, and the fourth opening 957 may be formed to be spaced apart from each other in the horizontal directions (X and Y directions). A planar area of the first opening 951 may be greater than a planar area of each of the second opening 953, the third opening 955, and the fourth opening 957. The planar area of the first opening 951 may be greater than the planar area of the second chip 400.

The second opening 953 may be formed to overlap the second chip 400 in the vertical direction Z. The third opening 955 may be formed to overlap the second conductive pillar 480 in the vertical direction Z. The fourth opening 957 may be formed to overlap the third conductive pillar 380 in the vertical direction Z.

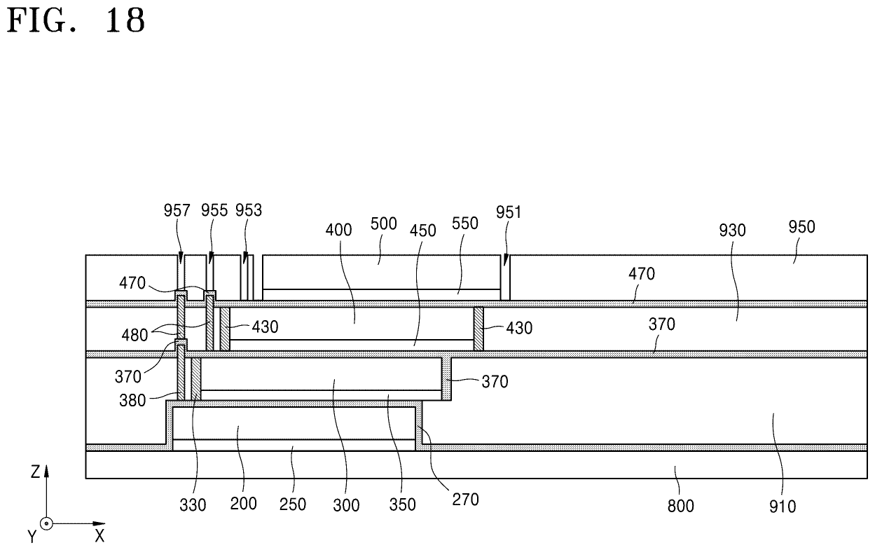

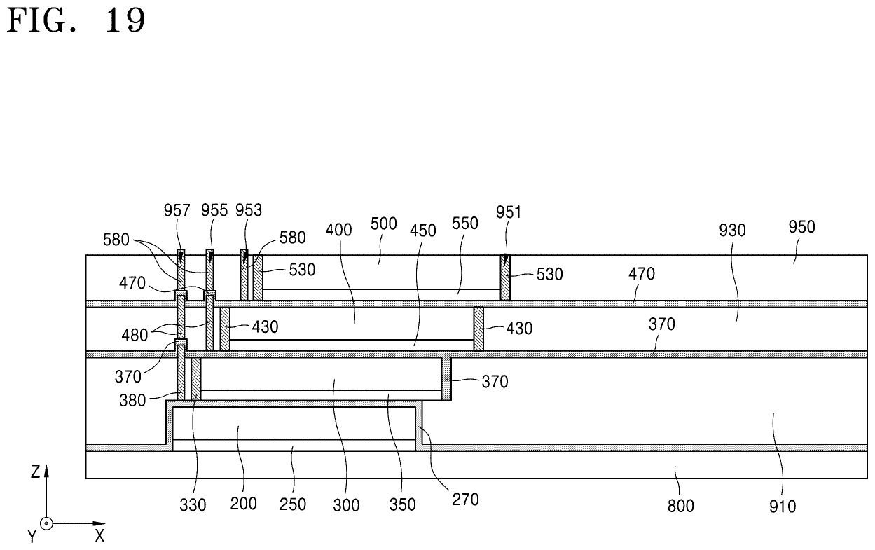

Referring to FIG. 18 and FIG. 19, the first chip 500 may be mounted in the first opening 951, the first metal layer 530 may be formed in a space between the first opening 951 and the first chip 500 by using the first seed layer 470, and the first conductive pillar 580 may be formed in each of the second opening 953, the third opening 955, and the fourth opening 957. The first chip 500 may be mounted in the first opening 951 by using the first adhesive layer 550. At least one side surface of the first chip 500 may be spaced apart from the third photoresist 950 in the horizontal directions (X and Y directions). Accordingly, a remaining portion of the first opening 951 may be provided between the first chip 500 and the third photoresist 950. The side surface of the first chip 500 may be surrounded by the first metal layer 530.

According to some embodiments, the vertical level of the upper surface of the first conductive pillar 580 formed in each of the second opening 953, the third opening 955, and the fourth opening 957 may be variously formed.

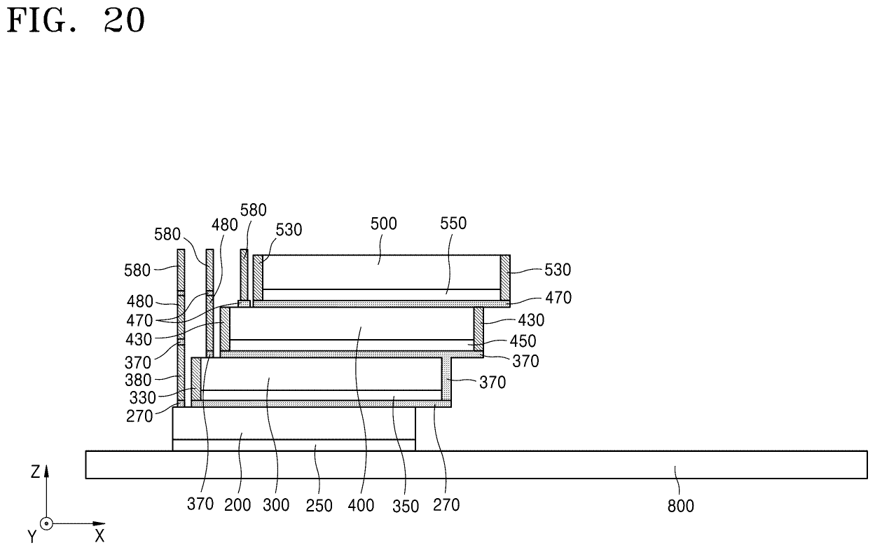

Referring to FIG. 20, the first photoresist 910, the second photoresist 930, and the third photoresist 950 may be removed, and a portion of each of the first seed layer 470, the second seed layer 370, and the third seed layer 270 may be removed.

In this case, the first seed layer 470 may remain on a bottom surface of the first adhesive layer 550, the bottom surface of the first metal layer 530, and a bottom surface of each of the first conductive pillars 580; the second seed layer 370 may remain on a bottom surface of the second adhesive layer 450, the bottom surface of the second metal layer 430, and the bottom surface of each of the second conductive pillars 480; and the third seed layer 270 may remain on a bottom surface of the third adhesive layer 350, the side surfaces of the third chip 300, the bottom surface of the third metal layer 330, and the bottom surface of the third conductive pillar 380.

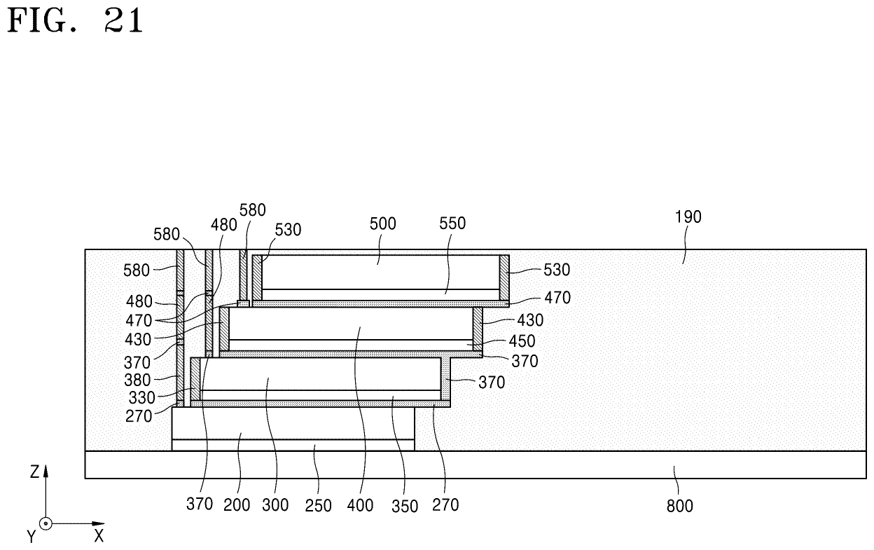

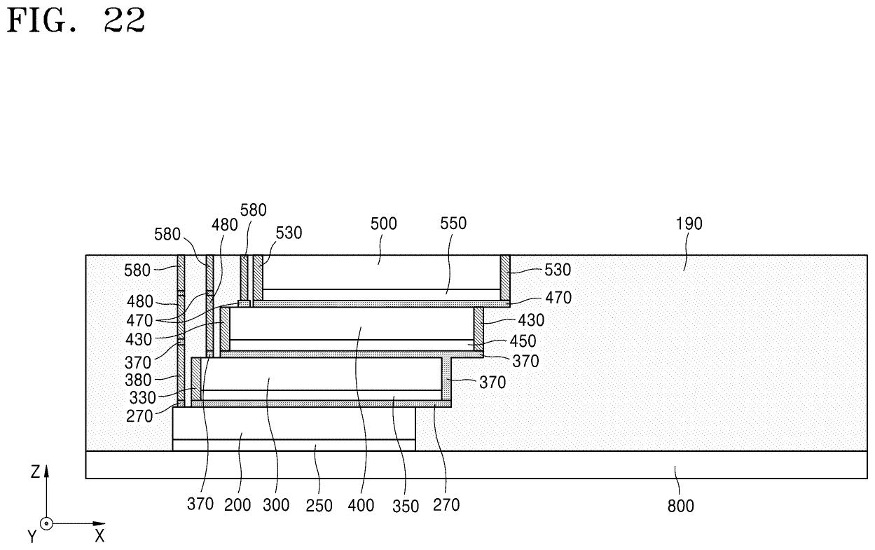

Referring to FIG. 21 and FIG. 22, the molding member 190 covering the first through fourth chips (200, 300, 400, and 500) may be formed on the carrier substrate 800. The molding member 190 may surround sidewalls of the first conductive pillars 580, wherein upper portions of the first conductive pillars 580 may be exposed. Alternatively, the molding member 190 may cover the first conductive pillars 580. The molding member 190 and the first conductive pillars 580 may be planarized, for example, by grinding. The planarization may expose the upper surface of the first conductive pillars 580 in a case that the molding member 190 covers the first conductive pillars 580. The planarization may expose the upper surface of the molding member 190. The molding member 190 and the first conductive pillars 580 may be planarized, and the upper surface of the molding member 190 and the upper surfaces of the first conductive pillars 580 may be disposed at the same vertical level as the upper surface of the first chip 500. For example, the upper surface of the molding member 190 and the upper surfaces of the first conductive pillars 580 may be co-planar.

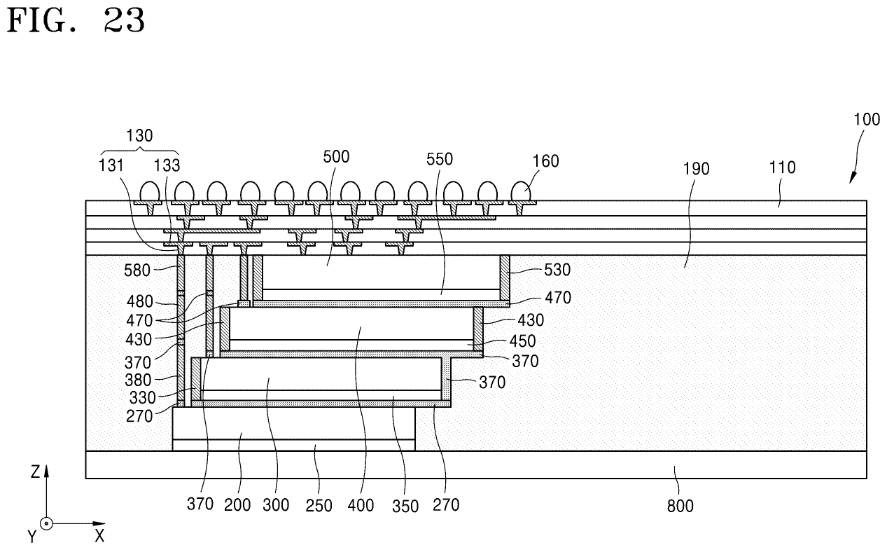

Referring to FIG. 23, the rewiring structure 100 may be formed on the upper surfaces of the molding member 190, the first conductive pillars 580, and the first chip 500. Further, the external connection bump 160 may be formed on the upper surface of the rewiring structure 100.

While the inventive concept has been particularly shown and described with reference to embodiments thereof, it will be understood that various change in form and details may be made therein without departing from the spirit and scope of the following claims.

What is claimed is:

1. A semiconductor package comprising:
a rewiring structure;
a first chip on the rewiring structure;
a first adhesive layer on an upper surface of the first chip;
a first seed layer on an upper surface of the first adhesive layer;
a first metal layer on a side surface of the first chip;
a first conductive pillar on the rewiring structure and spaced apart from the first metal layer in a first horizontal direction;
a second chip on an upper surface of the first seed layer, and offset stacked from the first chip in the first horizontal direction; and
a second adhesive layer on an upper surface of the second chip,
wherein the first conductive pillar overlaps the second chip in a vertical direction, and
a portion of the first seed layer is disposed between the first conductive pillar and the second chip.

2. The semiconductor package of claim 1, wherein the first chip comprises a logic chip,
the second chip comprises a memory chip, and
a number of first chip pads of the first chip is greater than a number of second chip pads of the second chip.

3. The semiconductor package of claim 1, wherein a thickness of the first metal layer in a horizontal direction is in a range of about 1 micrometers (μm) to about 50 μm.

4. The semiconductor package of claim 1, further comprising a molding member surrounding the first chip and the second chip and on an upper surface of the rewiring structure,
wherein an upper surface of the molding member is coplanar with an upper surface of the second adhesive layer.

5. The semiconductor package of claim 1, wherein the first chip comprises a plurality of side surfaces, including the side surface, and at least one side surface among the plurality of side surfaces of the first chip is covered by the first metal layer, and at least another side surface among the plurality of side surfaces is covered by the first seed layer.

6. The semiconductor package of claim 1, further comprising:
a second seed layer configured to cover an upper surface of the second adhesive layer;
a second metal layer configured to cover at least one side surface among a plurality of side surfaces of the second chip;
a second conductive pillar on the rewiring structure and spaced apart from the second metal layer in the first horizontal direction; and
a third chip offset stacked on the upper surface of the second chip in the first horizontal direction,
wherein the second conductive pillar overlaps the third chip in the vertical direction,
wherein a plurality of first conductive pillars, including the first conductive pillar, is provided, at least one first conductive pillar of the plurality of first conductive pillars overlaps the second chip in the vertical direction, and at least another first conductive pillar of the plurality of first conductive pillars overlaps the second conductive pillar in the vertical direction, and
wherein a first portion of the second seed layer is between the first conductive pillar and the second conductive pillar.

7. The semiconductor package of claim 6, wherein a second portion of the second seed layer is between the second conductive pillar and the third chip.

8. The semiconductor package of claim 6, wherein a lower surface of the second conductive pillar is at a vertical level lower than a lower surface of the second metal layer.

9. The semiconductor package of claim 6, wherein a lower surface of the second conductive pillar is at a vertical level higher than a lower surface of the second metal layer.

10. The semiconductor package of claim 6, wherein a planar area of the first seed layer is greater than a planar area of the first chip, and
a planar area of the second seed layer is greater than a planar area of the second chip.

11. A semiconductor package comprising:
a rewiring structure;
a first chip on the rewiring structure;
a first adhesive layer on an upper surface of the first chip;
a first seed layer on an upper surface of the first adhesive layer;
a first metal layer covering a side surface of the first chip;
a plurality of first conductive pillars on the rewiring structure and spaced apart from the first metal layer in a first horizontal direction;
a second chip on an upper surface of the first seed layer, and offset stacked from the first chip in the first horizontal direction;
a second adhesive layer on an upper surface of the second chip;
a second seed layer on an upper surface of the second adhesive layer;
a second metal layer covering a side surface of the second chip;
a plurality of second conductive pillars on at least some of the plurality of first conductive pillars and spaced apart from the second metal layer in the first horizontal direction;
a third chip on an upper surface of the second seed layer, and offset stacked from the second chip in the first horizontal direction;
a third adhesive layer on an upper surface of the third chip;
a third seed layer on an upper surface of the third adhesive layer;
a third metal layer covering a side surface of the third chip;
a third conductive pillar on a second conductive pillar of the plurality of second conductive pillars and first conductive pillar of the plurality of first conductive pillars, and spaced apart from the third metal layer in the first horizontal direction;
a fourth chip on an upper surface of the third seed layer, and offset stacked from the third chip in the first horizontal direction; and
a fourth adhesive layer on an upper surface of the fourth chip,
wherein the third conductive pillar overlaps the fourth chip in a vertical direction,
wherein at least one second conductive pillar of the plurality of second conductive pillars overlaps the third chip in the vertical direction, and
wherein at least one first conductive pillar of the plurality of first conductive pillars overlaps the second chip in the vertical direction.

12. The semiconductor package of claim 11, wherein a portion of the first seed layer is disposed between the first conductive pillar and the second conductive pillar, and
wherein a portion of the second seed layer is disposed between the second conductive pillar and the third conductive pillar.

13. The semiconductor package of claim 11, further comprising a molding member surrounding the first chip, the second chip, the third chip, and the fourth chip and on an upper surface of the rewiring structure.

14. The semiconductor package of claim 13, wherein an upper surface of the molding member is coplanar with an upper surface of the fourth adhesive layer.

15. The semiconductor package of claim 11, wherein a thickness in a horizontal direction of each of the first metal layer, the second metal layer, and the third metal layer is in a range of about 1 micrometers (μm) to about 50 μm.

16. The semiconductor package of claim 11, wherein an upper surface of the first conductive pillar is disposed substantially at a vertical level of an upper surface of the first metal layer,
wherein an upper surface of the second conductive pillar is disposed substantially at a vertical level of an upper surface of the second metal layer, and
wherein an upper surface of the third conductive pillar is disposed substantially at a vertical level of an upper surface of the third metal layer.

17. The semiconductor package of claim 11, wherein the third chip comprises a plurality of side surfaces, including the side surface of the third chip, and
at least one side surface among the plurality of side surfaces of the third chip is covered by the second seed layer.

18. A semiconductor package comprising:
a rewiring structure including a rewiring pattern and a rewiring insulating layer covering the rewiring pattern;
a first chip on the rewiring structure;
a first adhesive layer on an upper surface of the first chip;
a first seed layer covering the upper surface of the first adhesive layer;
a first metal layer extending from the first seed layer, covering side surfaces of the first chip, and in contact with the rewiring structure;
a plurality of first conductive pillars on the rewiring structure and spaced apart from the first metal layer in a first horizontal direction;
a second chip on an upper surface of the first seed layer, and offset stacked from the first chip in the first horizontal direction;
a second adhesive layer on an upper surface of the second chip;
a second seed layer covering an upper surface of the second adhesive layer;
a second metal layer extending from the second seed layer to a lower surface of the second chip in a vertical direction, and covering side surfaces of the second chip;
a plurality of second conductive pillars overlapping at least some of the plurality of first conductive pillars in a vertical direction, and spaced apart from the second metal layer in the first horizontal direction;
a third chip on an upper surface of the second seed layer, and offset stacked from the second chip in the first horizontal direction;
a third adhesive layer on an upper surface of the third chip;
a third seed layer on an upper surface of the third adhesive layer;
a third metal layer extending from the third seed layer, and covering at least one side surface among a plurality of side surfaces of the third chip;
a third conductive pillar overlapping a second conductive pillar of the plurality of second conductive pillars in the vertical direction, and spaced apart from the third metal layer in the first horizontal direction;
a fourth chip on an upper surface of the third seed layer, and offset stacked from the third chip in the first horizontal direction;
a fourth adhesive layer on an upper surface of the fourth chip; and
a molding member surrounding the first chip, the second chip, the third chip, and the fourth chip,
wherein the third conductive pillar overlaps the fourth chip in the vertical direction,
wherein at least one second conductive pillar of the plurality of second conductive pillars overlaps the third chip in the vertical direction,
wherein at least one first conductive pillar of the plurality of first conductive pillars overlaps the second chip in the vertical direction,
wherein a portion of the first seed layer is disposed between the at least some of the plurality of first conductive pillars and the plurality of second conductive pillars, a portion of the second seed layer is disposed between the second conductive pillar of the plurality of second conductive pillars and the third conductive pillar, and a portion of the third seed layer is disposed between the third conductive pillar and the fourth chip, and
wherein at least one side surface among the side surfaces of the third chip is covered by the second seed layer.

19. The semiconductor package of claim 18, wherein a thickness in a horizontal direction of each of the first metal layer, the second metal layer, and the third metal layer is in a range of about 1 micrometers (μm) to about 50 μm.

20. The semiconductor package of claim 18, wherein the rewiring pattern comprises a rewiring via pattern extending in the vertical direction, and a rewiring line pattern extending in a horizontal direction, and
wherein the rewiring via pattern has a tapered shape in which a horizontal width decreases as a vertical level increases.
